(19) United States
(12) Patent Application Publication
(10) Pub. No.: US 2014/0138425 A1
(43) Pub. Date: May 22, 2014

(54) METHOD FOR THE COHESIVE CONNECTION OF ELEMENTS

(71) Applicants: Stefan Meyer, Ronneburg (DE); Hilmar Von Campe, Bad Homburg (DE); Stephan Huber, Rechtmehring (DE); Sven BOHME, Niederschona (DE)

(72) Inventors: Stefan Meyer, Ronneburg (DE); Hilmar Von Campe, Bad Homburg (DE); Stephan Huber, Rechtmehring (DE); Sven BOHME, Niederschona (DE)

(21) Appl. No.: 14/117,895

(22) PCT Filed: May 15, 2012
(86) PCT No.: PCT/EP2012/059039

§ 371 Date: Feb. 5, 2014

(30) Foreign Application Priority Data
May 17, 2011 (DE) 10 2011 050 436.2
Jun. 10, 2011 (DE) 10 2011 051 024.9

(51) Int. Cl. H01L 23/00; B23K 20/10

(52) U.S. Cl. CPC H01L 24/80; B23K 20/10
USPC 228/111.5

(57) ABSTRACT

The invention relates to a method for the cohesive connection of a first element (16, 18) to a second element (10), wherein the elements are located one on the other during the connection process and are connected by means of a solder material which is subjected to ultrasonic vibrations during connection by means of a tool (32, 34). In order to allow cohesive connection in an energy-efficient manner, it is proposed that the first element (16, 18) used is one which has through-passage openings (28, 30), that for the purpose of connection the first element and the second element (10) are placed one on the other with through-passage openings open towards the second element, and that molten solder material is located in the through-passage openings during connection and in the through-passage openings the molten solder material is subjected to the ultrasonic vibrations.

The invention relates to a method for the cohesive connection of a first element such as the first connector to a second element such as the second connector and/or semiconductor component such as a solar cell, whereby the elements lie on one another during the connecting and are connected by solder material that is loaded during the connecting by a tool such as a sonotrode with ultrasonic oscillations, whereby the tool has a temperature T_{w} during the connection with in particular T_{w}≧Tₛ with Tₛ=the melting temperature of the solder material.

A method for applying a connection conductor on a solar cell is known from WO-A-2008/104900 (DE-A-10 2006 035 626) in which solder is applied on the solar cell by ultrasonic soldering. To this end the solder in the form of a solder wire or solder form parts is soldered on by an ultrasonic sonotrode at soldering temperature.

The soldering of solder on in particular solar cells by ultrasound has the advantage that a fluxing agent does not have to be used, as a result of which the danger of damage to the solar cell otherwise increases. The advantage also results that the subsequent lamination time in the module production can be shortened.

Furthermore, when using fluxing agents it is disadvantageous that contaminations of production systems occur or vapors dangerous to health can be produced.

Oxide layers present on the solar cells are broken up by the ultrasonic action in order to ensure a mechanically firm connection with good electrical connection between the solder and the corresponding metallic layer of the solar cell. This is particularly advantageous if the metallic layer is an aluminum layer such as a contact consisting of aluminum on the back side.

Corresponding ultrasonic soldering methods can also be gathered, e.g., from U.S. Pat. No. 6,357,649 or the literature citation Mardesich et al.; “A Low-Cost Photovoltaic Cell Process Based on Thick Film Techniques; 14^{th} IEEE PV, Sp. Conf. Proc., 1980, pages 943-947.

A method and a device for soldering connection connectors to a solar cell are known from EP-A 2 289 658. In it, connection contacts and a solar cell are arranged lying on one another in a stack arrangement, the stack arrangement is homogeneously heated and set on the connection contacts of a sonotrode applying ultrasonic oscillations. The connection conductors are coated on their top and bottom with a solder. The corresponding stack arrangement is then placed onto a heating device from which the required heating is transferred onto the stack arrangement. As a result, energy for the soldering without fluxing agent is supplied.

DE-A-22 36 699 relates to a connecting of parts without fluxing agent. For this a soldering piston is used that is put in oscillation with a frequency less than 1000 Hz.

DE-A-41 04 160 describes the connecting of solar cell contact elements that make possible a relative motion between the cells.

US-A-2005/0217718 teaches a method for connecting solar cells to a model. In order to connect two solar cells by a connector, the latter can extend through an opening of one of the solar cells in order to then be cohesively connected next to the opening to the solar cell, e.g., by ultrasound or by lasers.

The present invention has the basic problem of further developing a method of the initially cited type in such a manner that a cohesive connection can take place in an energy-efficient manner. At the same time there should be the possibility of introducing the solder material into the areas in which the cohesive connection, that is, the soldering of the elements to one another, should take place.

In order to solve the problem the invention essentially provides that an element is provided as the first element that comprises passage openings, that for the connection the first element and the second element are placed on one another with the passage openings open to the second element, that molten solder material is present during the connection in at least one of the passage openings or in the passage openings, and that the molten solder material in the passage opening is loaded with the ultrasonic oscillations.

In distinction to previously known methods it is not necessary that one of the elements is surrounded by a solder material. Rather, it is sufficient if solder material is introduced exclusively into the passage openings in order to connect the elements to one another. In particular, this creates the possibility that in the connecting of solar cells tinned series connectors are not required but rather series connectors that are not tinned and consist, e.g., of aluminum. In this manner economical materials with great strength can be economically used without the risk of a defective connection. Furthermore, there is the advantage due to the ultrasonic soldering technology used that the work can be carried out without fluxing agents.

Furthermore, there is the advantage that the solder material remains in a purposeful manner in the area of the passage opening and in the adjacent areas between the elements to be soldered since the passage opening forms a quasi collection position for the solder material and thus an uncontrolled distribution of solder material on the second element such as a solar cell does not take place. Consequently, the solder material does not result in undesired shading in as far as solder connections are produced in accordance with the invention on the front side, that is, on the side of the solar cell for the incident light. It is possible to make do with slight amounts of solder material since the solder material is located in a purposeful manner in the area where the cohesive connection is to be produced.

The solder material itself is melted in particular by contact with the tool by which the ultrasonic oscillations are applied and/or by a heating device. It is provided in particular that the solder material is applied to a slot running between the heating device and the tool and melted. The molten solder wets the area running on its connector side—such as the front surface of a sonotrode as the tool—that loads the solder in the passage opening with ultrasound.

The tip of the tool such as a sonotrode has a surface extension that is less than the passage opening so that the tool can move into the passage opening during the loading with ultrasound. However, as an alternative the contact surface of the tool with the solder can be greater than the passage opening so that the tip of the tool covers the passage opening and extends area-wise along the edge of the passage opening.

There is also the possibility that solder material is applied onto the solder material before the placing of the first electrode onto the second element in accordance with the arrangement of the passage openings in the first element. In this manner during the placing of the first element the solder material preferably applied in a punctiform manner previously onto the second element passes through the passage openings or extends into them in order to then align the tool, after the placing of the first electrode onto the second electrode, onto the individual passage openings and to apply the ultrasound.

The heat required to melt the solder material is then transmitted via the sonotrode that is appropriately heated up.

In particular, it is provided that the tool is introduced into the passage opening with a section during the cohesive connection. These measures bring about an optimal coupling of the ultrasonic oscillations into the molten solder material as well as into the second element—such as, e.g., the aluminum layer on the back side of a solar cell—with an optimal heat transfer at the same time.

It is preferably provided that a semiconductor component such as a solar cell or a current derivation (bus bar) of a semiconductor component is used as the second element and/or an electrically conductive connector such as a cell connector is used as the first element.

The cell connector can consist, in distinction to known connectors connecting solar cells, of another material than copper; in particular, they can consist of aluminum, so that an economical connector is made available that resists the mechanical loads to a sufficient extent.

Furthermore, it should be stressed that a semiconductor component with a front and a back side is used as the second element that is cohesively connected to the front as well as to the back side of at least one first element, whereby the cohesive connecting takes place simultaneously or in series in passage openings preferably along a common straight line passing vertically through the lower side and the top side.

The invention provides, in order to keep the mechanical loads on the elements, in particular on the semiconductor element such as a solar cell as the second element, as low as possible during the soldering, that is, the cohesive connecting, and the action of the ultrasonic oscillations, whereby the tool has a mechanical contact at least with the solder material, that the first and the second elements, that rest on each other and form a unit, are resiliently supported or mounted during the cohesive connecting in the direction of the workpiece and/or the workpiece is resiliently supported or mounted in the direction of the unit.

There is the possibility, independently of the above, that the unit is transported during the cohesive connecting and that the tool is moved with it at the same time. A stationary arrangement of the tool is also possible.

According to the invention a method for the electrical contacting and cohesive connection without fluxing agent is suggested, whereby one of the elements is in particular a solar cell and the other element is in particular a connector. The method can also be used between a cell connector and, e.g., a bus bar of a solar cell. The unit consisting of the elements is connected here to solder material loaded with ultrasound.

To this end the first element comprises recesses in the area of the tool applying the ultrasonic oscillation, which tool can also be designated as a sonotrode. The ultrasonic method used makes possible in this way a cohesive solder connection between the elements without fluxing agent.

The heat required to melt the solder material, is generated, in distinction to previously known solutions, not by heating the elements, in particular a solar cell, abut rather by the tool—optionally by a heating associated with it—and transmitted onto the solder material.

It is provided in an embodiment that is to be emphasized that a slot is formed between the heating device and the tool that applies the ultrasonic oscillations to which slot the solder material is supplied in particularly in wire form in in which the solder material is melted, and that then the molten solder cohesively connects the first and the second element by wetting the tool and by a subsequent insertion into the passage opening. The insertion takes place by the tool.

However, there is also the possibility of applying solder points on the second element such as a solar cell that does not comprise the passage openings, the arrangement of which solder points takes place in accordance with the arrangement of the passage openings in the first element, so that during the placing of the first element onto the second element the solder points are located in the passage openings. This type of measures are selected in particular when a device is to be connected to first elements on the top as well as on the bottom of the second element such as a semiconductor component, in particular a solar cell, and the second element spans a plane running horizontally.

If the solder material is supplied to the slot running between the heating device and the tool, the tool and the heating device should be heated to a temperature above the melting point of the solder, whereby the temperature of the heating device should preferably be adjusted independently of the temperature of the tool.

The heating device can be a heating body shaped like a block or a parallelepiped that preferably comprises on the workpiece side a projection limiting the slot and that preferably has a geometry like a section of a cylinder.

The solder material used is in particular one based on Sn—Zn, on Sn—Ag or consists of pure tin.

If the longitudinal axis of the tool preferably runs along the normal of a plane spanned by the second element, an angle deviating from this can be selected. The heating device must be aligned accordingly in order that the desired slot is available.

Other details, advantages and features of the invention result not only from the claims, the features to be gathered from them alone and/or in combination but also from the following description of the preferred exemplary embodiments to be gathered from the drawings.

In the drawings:

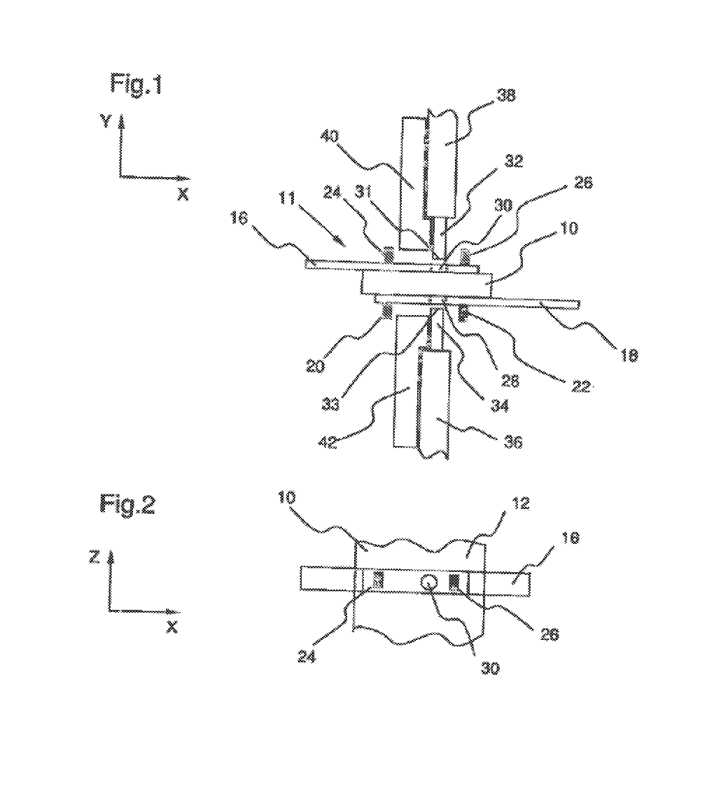

FIG. 1 shows a side view of an arrangement for the cohesive connecting of two first elements to a second element,

FIG. 2 shows a section of the arrangement in accordance with FIG. 1 in a top view,

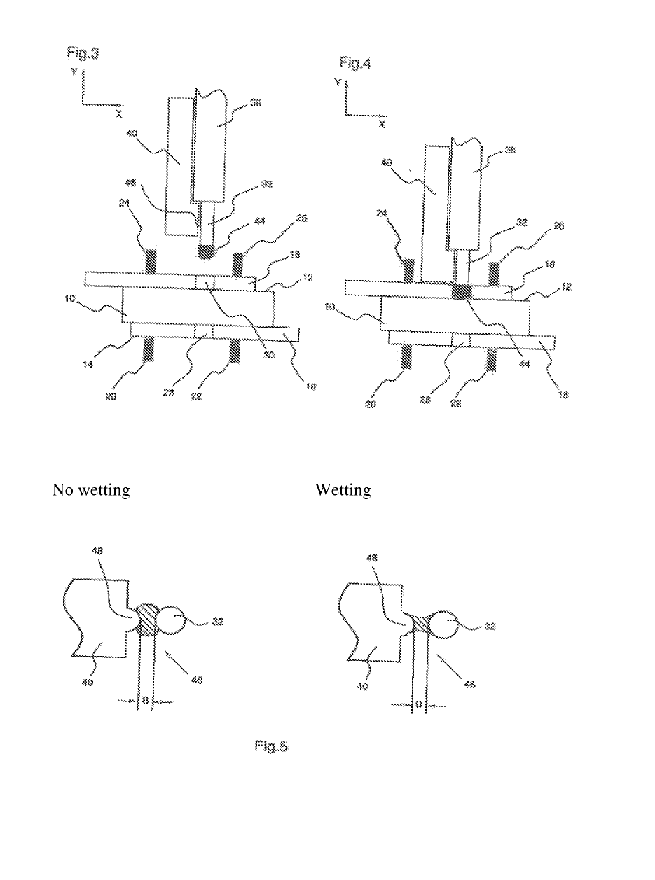

FIG. 3 shows another section of the arrangement in accordance with FIG. 1 before the cohesive connection,

FIG. 4 shows a view corresponding to FIG. 3 during the cohesive connection,

FIG. 5 shows sections of a sonotrode and of a heating device associated with it,

FIG. 6 shows a basic view of the wetting of a front surface of a sonotrode, and

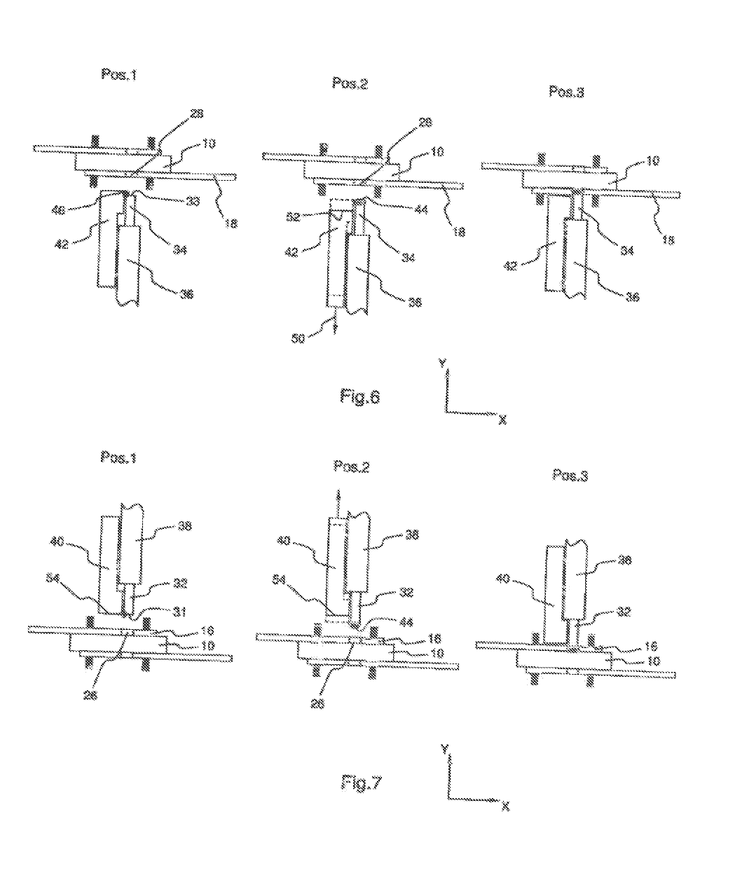

FIG. 7 shows another basic view of the wetting of a front surface of a sonotrode.

The teaching in accordance with the invention is explained in the following using the soldering of strip-shaped connection conductors to the front and the back side of a solar cell without the teaching of the invention being limited by this but rather the soldering can take place even of connectors among themselves or of other types of the electrically conductive elements.

According to the invention the soldering, that is, the cohesive connecting of a solar cell 10, i.e., its top 12 and its bottom 14, to serial connectors 16, 18 is supported by ultrasound without a fluxing agent being required. To this end a compound, that can also be designated as unit 11, consisting of the solar cell 10 and the connectors 16, 18 running along the top side 12 and the bottom side 14 is arranged between support elements or fixing elements 20, 22, 24, 26 between which the unit 11 can be positioned in such a manner that the soldering of the connectors 16, 18 to the upper- or bottom side 12, 14 of the solar cell 10 can take place in different areas in the manner described below.

The supports 20, 22, 24, 26 preferably offer a resilient fixing of the unit 11 in such a manner that during the cohesive connecting a deviation of the forces acting on the unit 11 takes place to the required extent so that the mechanical load is minimized.

The fixing elements 20, 22, 24, 26 can also be transport bands for being able to transport the unit 11 in the X direction in the exemplary embodiment.

The transport bands would on the one hand fix the unit 11 in the exact position and on the other hand resiliently support the unit 11 to the extent required.

Resilient support means here that the unit 11 can be adjusted in the Y direction, whereby the travel stroke can be in the range of ±1 mm.

Resilient mounting denotes a movement of the unit 11 or of the sonotrodes 32, 34 in the Y direction independently of the intrinsic elasticity of the components themselves. The resilience can take place via appropriate springs or via a support with a desired spring characteristic.

In order to solder the connectors 16, 18 to the upper- or bottom sides 12, 14 of the solar cell 10 the following measures are provided in accordance with the invention.

The connectors 16, 18 comprise passage openings 28, 30 in which in the case of the connectors 16, 18 placed on the solar cell 10 the surfaces of the upper- and bottom sides 12, 14 of the solar cell 10, which sides are present below and above the solar cells 28, 30, are exposed. The passage openings 26, 28 have a suitable geometry, in particular a circular geometry or elongated hole geometry, but also a rectangular geometry. For example, a circular hole geometry is shown in sketched in FIG. 2.

During the soldering the passage openings 28, 30 are positioned in such a manner that they are above and below these front surfaces of tools 32, 34 with a cylindrical geometry to be designated as sonotrodes. The tools 32, 34, that are designated in the following as sonotrodes, are surrounded by a heating jacket 36, 38 in order that the sonotrodes 32, 34 can be heated in their area not surrounded by the heating jacket 36, 38 to a temperature that is equal to the melting temperature Tₛ of the soldering material or is above it by means of which the connectors 16, 18 are soldered to the upper- and bottom sides 12, 14 of the solar cell 10.

There are various possibilities for introducing the solder material into the passage openings 28, 30. Thus, the sonotrode 32 can be associated with a heating device 40, 42 that is aligned in such a manner relative to the sonotrodes 32, 34 that a slot is formed in which the solder material is supplied in the form of a solder wire. This is possible regarding the arrangement of sonotrode 32 that runs above the unit 11.

The heating device 40 and the sonotrode 32 are heated to a temperature that is above the melting temperature Tₛ of the solder wire or corresponds to it. Thus, the solder material melts during the introduction of the solder wire into the slot formed between the heating device 40 and the sonotrode 32. At the same time the sonotrode 32 is excited in ultrasonic oscillations so that the solder material can wet the sonotrode 32 and flows to the front surface 31. Subsequently, the wetted front surface 31 is lowered onto the passage opening 30 and optionally inserted into it. Therefore, the solder material passes into the passage opening 30.

At the same time the ultrasonic oscillations are transmitted onto the solder present in the passage opening 30 in order to make possible the soldering supported by ultrasound. Accordingly, the sonotrode 34 is moved with its front surface 33 to the passage opening 28 in order to then carry out the cohesive connection with the solder material present in the passage opening 28 with ultrasonic support.

In the exemplary embodiment the front surface 31 of the sonotrode has a cross section that is smaller than that of the passage opening 30 so that the sonotrode 32 can enter with its tip, that is, its front surface 31, into the passage opening 30. However, this is not an obligatory feature.

Accordingly, a cohesive connection of the connector 18 to the bottom 10 of the solar cell 14 can take place. In this instance, according to an alternative, soldering points can be applied on the bottom 14 at a distance corresponding to the distance of the passage openings 28 in the connector 18, so that during the positioning of the connector 18 on the bottom 14 of the solar cell 10 the soldering points pass through the passage openings 28. However, there is also the possibility of first wetting the front surface 33 of the sonotrode 34 that runs parallel—corresponding to the front surface 31 of the sonotrode 32—to the planes spanned by the solar cell 10 and to the connectors 16, 18, and then cohesively connecting the connector 18 to the solar cell 10 by introducing the solder material into the passage opening 28 and inserting the tip area of the sonotrode 34 into the passage opening 28.

However, there is also the possibility of first introducing solder material into the passage openings 28 of the connector 18, which material can then be melted into the passage openings 28 under the action of the sonotrode 34 heated to at least the melting temperature and thus the cohesive connection can be produced.

The sonotrodes 32, 34 can be moved to the passage openings 28, 30 by independent linear drives.

In order to align the passage openings 28, 30 with the sonotrodes 32, 34, the unit 11 is transported in the X direction. This can take place with the previously addressed transport bands or with means acting in the same manner.

If the passage opening 30 is in alignment with the sonotrode 32, the latter is lowered, during which a wetting without fluxing agent takes place in the boundary area between the connectors 16 and the top 12 of the solar cell 10. The sonotrode 32 is then moved back and the solder material hardens in the passage opening 30. A soldering of the connector 18 with a bottom 14 of the solar cell 10 takes place in a corresponding manner.

The cohesive connection of the connectors 16, 18 to the solar cell 10 can also take place at the same time if every sonotrodes 32, 34 is associated at the same time with a passage opening 28, 30, as can be gathered from the exemplary embodiment. It is provided in particular here that the longitudinal axes of the sonotrodes 28, 30 along a common straight line running vertically to the plane spanned by the solar cell 10, that is, along a common normal.

The soldering procedure is shown again in the FIGS. 3 and 4 in conjunction with the cohesive connecting of the connectors 16 to the top 12 of the solar cell 10.

In FIG. 3 the sonotrode 32 with the heating device 40 associated with it and limiting a slot 46 to the sonotrode 32 is located above the passage opening 30. Solder material flows via the slot 46 along the sonotrode 32 to its tip, that is, the front surface 31, whereby the sonotrode 32 is excited with ultrasound. Then, the sonotrode 32 is lowered with the heating device 40 in such a manner that the solder material 44 present in the front surface area penetrates into the passage opening 30 in order to wet, supported by ultrasound, the connector 16 and the top 12 of the solar cell 10. Subsequently, the sonotrode 32 with the heating device 40 is raised off again in the Y direction.

FIG. 5 shows a section of the sonotrode 32 and of the associated heating device 40, namely, in the area of the slot 46 running between them, in which slot the solder material to be melted is introduced in the form of a solder wire.

FIG. 5 illustrates that the width B of the slot 46, that is, the unobstructed diameter between the sonotrode 32 and the projection 48 projecting from the heating device 40 in the direction of the sonotrode 32 should be selected in such a manner that it preferably corresponds to between ½ D and D with D=diameter of the soldering wire. The width B extends in the longitudinal direction of the connector 16 and can be constant over the height or can widen out conically in the direction of the connector 16.

The heating body 40, as well as the sonotrode 32, is adjusted to a temperature that is in particular above the melting temperature of the soldering wire. Solder material is preferably used that melts in the range between 100° C. and 350° C. although the temperature can be between 80° C. and 600° C. The adjustment of the temperature of the heating body in the range of its projection 48 should take place independently of the adjusting of the temperature of the sonotrode 32.

According to the invention the soldering wire is supplied to the slot 46, during which the soldering wire melts. Regardless of the high surface tension, a wetting of the limitation of the slot 46 (see the right representation in FIG. 5) takes place when the sonotrode 32 is excited in ultrasonic oscillation. This has the consequence that the molten solder can flow through the slot 46 along the sonotrode 32 to its tip, that is, front surface 31.

The left representation in FIG. 5 shows the molten solder with sonotrode 32 not put in oscillations.

The sonotrode 32, 34 can furthermore execute an oscillating movement during the transmission of the ultrasonic oscillation onto the solder material vertically to its longitudinal axis.

In particular, the melting of the solder material takes place in the slot running between the sonotrode 32, 34 and the associated heating 40, 42 directly in the area of the particular front surface 32, 34, so that the latter can be wetted with the solder material. This should be explained using the FIGS. 6 and 7 in which the same reference numerals are used for the same elements in FIGS. 1 to 5.

FIG. 6 is intended to explain the wetting of the sonotrode 34 with the associated heating 42 arranged below the connector 18 in the solar cell 10. In pos. 1 the heating 42 is aligned in such a manner to the front surface 33 of the sonotrode 34 that a soldering wire is supplied to the slot running between the heating 42 and the sonotrode 34, that is located in the area of the front surface 33, so that after the melting of the solder material the front surface 33 is wetted with solder. Then, the heating is moved in accordance with the phantom representation in pos. 2 in the direction of the arrow 50 relative to the sonotrode 34 so that as a consequence the front surface 33 with the solder material 44 runs at a distance from the front surface 52 of the heating 42, which front surface runs on the connector side. Then, the sonotrode 34 is moved together with the heating 42 in the direction of the connector 10, as results from the pos. 3. The solder material 44 passes into the passage opening 28, whereby the sonotrode 34 optionally engages with its front area 33 into the passage opening 28. As a result of these measures the cohesive connection between the connector 18 and the solar cell 10 can be realized.

The cohesive connection between the connector 16 and the solar cell 10 is shown purely schematically in a corresponding manner in FIG. 7. In pos. 1 the front surface 54 of the heating 40, which surface runs on the connector side is preferably in alignment with or approximately in alignment with the front surface 31 of the sonotrode 32. A soldering wire is preferably introduced into the slot formed between the heating 40 and the sonotrode 32, namely, in the area of the front surface 31 and therewith of the front surface 54, so that solder melts with the result that the front surface 31 is wetted with solder material, as pos. 2 illustrates.

The soldering point 44 present on the front surface 31 is then introduced into the passage opening 21 by lowering the sonotrode 32 in the direction of the passage opening 26 into the latter in order to cohesively connect the connector 16 to the solar cell 10. A relative motion between the sonotrode 32 and the heating 40 preferably took place in such a manner that the front surface 54 of the heating 40 runs set back relative to the front surface 31 of the sonotrode 32, as the pos. 2 illustrates with the phantom lines.

It should be noted regarding the passage openings 28, 30 that they should have, in case of a circular geometry, a diameter between 0.01 mm to 10 mm and in the case of a rectangular geometry they should have shank lengths between 1 mm and 150 mm.

The volume of solder material that can be introduced into a passage opening 28, 30 can be between 0.01 mm³ and 100 mm³, preferably, however, between 0.05 mm³ and 0.25 mm³.

1. A method for the cohesive connection of a first element (16, 18) such as the first connector to a second element (10) such as the second connector and/or semiconductor component such as a solar cell, whereby the elements lie on one another during the connecting and are connected by solder material that is loaded during the connecting by a tool (32, 34) such as a sonotrode with ultrasonic oscillations, whereby the tool has a temperature Tw during the connection with in particular Tw>Ts with Ts=the melting temperature of the solder material,
characterized in that,
an element is provided as the first element (16, 18) that comprises passage openings (28, 30),
for the connection the first element and the second element (10) are placed on one another with the passage openings open to the second element,
and
that molten solder material is present during the connecting in at least one of the passage openings, and the molten solder material in the passage opening is loaded with the ultrasonic oscillations.

2. The method according to claim 1,
characterized in that,
the solder material is melted by contact with the tool (32, 34) and/or with a heating device (40, 42.

3. The method according to claim 2,
characterized in that,
the solder material is supplied to a slot (46) running between the heating device (40) and the tool (32), is melted and flows through the slot along the tool in the direction of the area of the tool running on the connector side such as the front surface (31) of a sonotrode (32) as the tool.

4. The method according to claim 1,
characterized in that,
prior to the placing of the first element (16, 18) onto the second element (10) solder material is applied on the first element in accordance with the arrangement of the passage openings (28, 30).

5. The method according to claim 1,
characterized in that,
the tool (32, 34) is introduced into the passage opening (28, 30) during the cohesive connection with a section or its front surface (31, 33) on its element side.

6. The method according to claim 1,
characterized in that,
a semiconductor component such as a solar cell (10) or a current derivation (bus bar) of a solar cell is used as the second element and an electrically conductive connector such as a cell connector is used as the first element (16, 18).

7. The method according claim 1,
characterized in that,
a solar cell (10) with a front and a back side (12, 14) is used as the second element, and that at least one first element (16, 18) is cohesively connected to the front—as well as to the back side, whereby the cohesive connecting takes place simultaneously or in series in passage openings (28, 30) preferably along a common straight line passing vertically through the lower side and the top side.

8. The method according to claim 1,
characterized in that,
the first and second elements (10, 16, 18) that rest on one another and form a unit (11) are resiliently supported during the cohesive connection in the direction of the workpiece (32, 34) and/or the workpiece is resiliently supported in the direction of the unit.

9. The method according to claim 1,
characterized in that,
the unit (11) is transported during the cohesive connection and that the tool (32, 34) is synchronously moved with it.

10. The method according to claim 1,
characterized in that,
a connector free of solder, in particular a connector consisting of aluminum or containing aluminum is used as the first element (16, 18).

11. The method according to claim 1,
characterized in that,
a soldering wire is used as solder material that is supplied to a slot (46) formed between a heating device (40) and the tool (32) and is melted.

12. The method according to claim 1,
characterized in that,
the tool (32, 34) and the heating device (40, 42) are heated to a temperature above the melting temperature Ts of the solder material, whereby the temperature of the heating device is preferably adjusted independently of the temperature of the tool.

13. The method according to claim 1,
characterized in that,
the solder material used is one based on Sn—Zn, on Sn—Ag or in particular consists of pure tin.

14. The method according to claim 1,
characterized in that,
the solder material is supplied directly in the area of the front surface (31, 33) of the sonotrode (32, 34) to the slot (46) between the latter and the associated heating device (40, 42), and that before or during the moving of the sonotrode (32, 34) in the direction of the passage opening (26, 28) the heating device (40, 42) is moved relative to the sonotrode (32, 34).
